(19) United States
(12) Patent Application Publication
(10) Pub. No.: US 2006/0097324 A1
(43) Pub. Date: May 11, 2006

(54) Semiconductor integrated circuit and method for designing the same

(75) Inventors: Katsuya Arai, Kyoto (JP); Katsuhiro Otani, Nara (JP); Kyoji Yamashita, Kyoto (JP); Daisaku Ikoma, Osaka (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/270,662

(22) Filed: Nov. 10, 2005

(30) Foreign Application Priority Data
Nov. 10, 2004 (JP) JP 2004-326838

(51) Int. Cl. H01L 23/62

(52) U.S. Cl. 257/357

(57) ABSTRACT

A first-conductive-type doped layer is provided on a second-conductive-type well, and a gate electrode of a MOS transistor and the first-conductive-type doped layer are connected to each other via a plug for filling a contact hole and a metal interconnect of Cu. Furthermore, a second-conductive-type doped layer is provided on a first-conductive-type well, and a gate electrode of a MOS transistor and the second-conductive-type doped layer are connected to each other via a plug for filling a contact hole and a metal interconnect of Cu. Then, a first diode and a second diode are provided between the gate electrode and the second-conductive-type well and between the gate electrode and the first-conductive-type well, respectively. Thus, antenna damage generated in the gate electrodes of the MOS transistors is prevented.

### CROSS-REFERENCE TO RELATED APPLICATION

This application claims priority under 35 U.S.C. §119(a) on Japanese Patent Application No. 2004-326838 filed on Nov. 10, 2004, the entire contents of which are hereby incorporated by reference.

### BACKGROUND OF THE INVENTION

1. Field of the Invention

The present invention relates to semiconductor integrated circuits, and more particularly relates to a semiconductor integrated circuit in which measures are taken to prevent antenna effect caused in plasma processing in metal interconnect formation of a semiconductor process.

2. Prior Art

In recent years, various kinds of plasma techniques have been used in a wiring process of a semiconductor process. Typical plasma techniques are, for example, dry etching used in patterning an interconnect layer, plasma TEOS deposition for forming an interlevel insulation film in a multi-layer wiring process, and the like. Hereinafter, such typical plasma techniques are collectively called “plasma processing”.

For example, in performing plasma etching, plasma charges are stored in a metal interconnect which is not connected to a doped layer of a semiconductor element. When charges exceeding a breakdown voltage of a gate oxide film of a transistor connected to the metal interconnect are stored, stored charges are discharged via the gate oxide film. As a result, the gate oxide film is broken down, transistor characteristics are changed due to change in the film quality of the gate oxide film, a hot carrier life-time is reduced, and some other inconvenience occurs. This phenomenon is called “antenna effect” and, hereinafter, an inconvenience caused by the antenna effect is referred to as “antenna damage”.

Antenna damage becomes worse when a finer design rule for semiconductor process is achieved. Factors of antenna damage are as follows. First, a gate oxide film of a transistor itself becomes a thin film and a breakdown voltage of the gate oxide film is reduced to a considerable extent, compared to the known process. Second, a minimum gate width is reduced as a design rule of semiconductor process becomes finer, whereas an interconnect length is not reduced so much even if a finer design rule for a semiconductor process is achieved. Another factor is that there is the tendency that even when over-etching occurs in dry etching of an interconnect, in order to ensure electromigration resistance of the interconnect and control a resistance value thereof, the thickness of an interconnect film can not be reduced so significantly while an interconnect width can be reduced. Furthermore, as a fourth factor, a plasma density in etching tends to be increased as an interconnect pattern becomes finer.

Because of the above-described factors, with an antenna ratio of 100,000, even though there has been no problem in the known 0.8 μm design rule CMOS generation and the like, antenna damage might occur in a finer process device. For example, in the case of a recent fine process (such as the 0.13 μm design process), antenna damage such as the occurrence of breakdown of a gate oxide film in the middle of a fabrication process step and deterioration of characteristics of a transistor might be caused in an LSI fabricated according to a general design even if the antenna ratio is at a level of about several thousands. Herein, in general, “antenna ratio” means to be the ratio between an area of a conductive layer in which plasma charges generated in plasma etching are stored and an area of a gate oxide film. Against this background, besides ESD protection for I/O ports in implementation and treatment thereof, which has been conventionally required, measures against electrostatic discharge have to be taken in a chip in consideration of wafer diffusion process. Note that antenna damage does not always occur when an antenna ratio is a predetermined level or more. Thus, it should be taken into consideration that if an interconnect to be processed in plasma processing is connected to a doped layer, plasma charges are released via the doped layer and antenna damage is not caused in a gate oxide film.

Next, a specific example for a known measure taken in the case where the antenna damage or an antenna rule error occurs in actual LSI designing will be described.

FIG. 6 is a flow chart illustrating a known measure against antenna damage. In an example of FIG. 6, cell arrangement correction for preventing antenna damage and an antenna rule error is performed using a designing support apparatus 502. First, a repeater cell including an n+ doped layer—p-type well protective diode or a p+ doped layer—n-type well antenna protective diode for preventing the occurrence of antenna damage or an antenna rule error of an antenna connected to a buffer, an inverter or an input pin of a buffer or an inverter is registered by register means 511 beforehand. In judgment means 514, it is judged whether an interconnect conductor conducted to a gate electrode has an antenna ratio exceeding an antenna ratio which is allowable in a semiconductor device. If the interconnect conductor has an antenna ratio exceeding the allowable antenna ratio, one or more repeater cells are inserted in arbitrary locations, respectively, by insertion means 515 so as to divide the interconnect conductor. Thus, even in a location where the antenna ratio is large, charges generated in plasma processing can be released via a diode. Therefore, the occurrence of antenna damage or an antenna rule error can be suppressed.

### SUMMARY OF THE INVENTION

However, the above-described known measure to prevent antenna damage or an antenna rule error has the following problems. As a first problem, additional correction for an antenna rule error is needed. Another problem is that there is no clear and effective method which can be used when error correction is automated using a CAD tool. Specifically, at present, a CAD automatic placement and routing tool does not have the function of avoiding an antenna rule error beforehand and, therefore, an antenna rule error, which is to be found at a one-chip interconnect layout stage, i.e., a stage close to an end of designing can not be prevented. Therefore, under present circumstances, a designer manually adds an antenna protective diode or performs some other remedy to correct an error found at a stage where a mask order is about to be placed. As has been described, according to a known design method, reversion to a previous process step occurs and unexpected manual operation has to be performed. This has been a biggest problem of design automation.

Furthermore, there is another inconvenience. That is, some constraints are imposed on design style. In recent years, if a process step which can be performed in parallel with layout designing is used, the process step and layout designing are performed in parallel. By doing so, a time required for designing to fabrication of an LSI is reduced. For example, when in a stage where block level designing for a chip is completed, chip blocks are arranged, a mask order based on a base is placed, and then diffusion is started, layout designing proceeds in parallel to those processes. Therefore, in later designing, when an antenna rule error is found in layout designing of an upper layer using an aluminum interconnect, it is not possible to modify a lower layer design to correct the antenna rule error. In such a case, an error is avoided by wiring. That is, restrictions are imposed so that a metal interconnect in which an antenna rule error is caused is used for an even upper layer or like method is performed. By doing so, the metal interconnect is connected to a doped layer at the time of etching an interconnect and the antenna rule error is corrected. However, if the number of design modification is increased, a number of corrections are given to a chip on which an interconnect layout has been successfully done. Accordingly, an interconnect pattern and how dense the chip is with the upper aluminum interconnect are largely changed. As a result, when re-wiring is performed, the metal interconnect can not be made to settle on the chip having the same area as before correction of the antenna rule error, a timing error in logic circuit designing, which has not occurred before the correction of the antenna error, occurs due to the change in interconnect pattern and how dense the chip is with the upper aluminum interconnect, and some other inconvenience arises.

The present invention has been devised in view of the above-described problems. It is therefore an object of the present invention to provide a semiconductor integrated circuit in which antenna damage caused in plasma processing of semiconductor process can be avoided without causing reversion of designing.

To solve the above-described problems, a semiconductor integrated circuit according to the present invention is a semiconductor integrated circuit designed using a standard cell. In the standard cell, at least one diode and one or more MOS transistors each comprising a gate electrode are provided, the diode being electrically connected to the gate electrode.

Thus, for example, in ASIC designing of a standard cell methodology or the like, a protective diode for preventing the occurrence of antenna damage or an antenna rule error is added beforehand to an input terminal of each cell in which an interconnect of which an antenna ratio has not been determined is to be provided. Thus, unlike the known design method, layout correction after an execution of layout, such as adding a protective diode to part of a chip in which an antenna rule error has occurred after an execution of chip layout, becomes no longer needed. Therefore, design efficiency in designing a semiconductor integrated circuit can be improved and a design period can be reduced.

In one embodiment of the present invention, the diode includes a first-conductive-type doped layer electrically connected to the gate electrode and a second-conductive-type well. Thus, the diode can be preferably added while increase in a chip area can be suppressed.

It is preferable that as the one or more MOS transistors, a plurality of MOS transistors are provided in the standard cell so as to share the gate electrode, and the plurality of MOS transistors includes a p-type MOS transistor and an n-type MOS transistor.

In one embodiment of the present invention, the diode is provided plural in number in the standard cell, the plurality of diodes include a first diode including a first-conductive-type doped layer electrically connected to the gate electrode, and a second-conductive-type well, and a second diode including a second-conductive-type doped layer electrically connected to the gate electrode, and a first-conductive-type well. Thus, both of positive plasma charges and negative plasma charges can be absorbed.

In one embodiment of the present invention, the gate electrode and the diode are electrically connected to each other via a shared contact. Thus, increase in a circuit area due to providing a diode can be suppressed.

In one embodiment of the present invention, the shared contact connects the gate electrode and the diode at each side of the gate electrode. Thus, a margin does not have to be provided in a connection portion of the gate electrode connected with the shared contact. Therefore, the width of the connection portion can be made to be the same as the width of the one or more MOS transistors and the shape of the gate electrode can be made to have dimensions close to expected values. Accordingly, variation in transistor characteristics of the one or more MOS transistors can be suppressed.

In one embodiment of the present invention, the gate electrode is provided plural in number in the standard cell, and diodes connected to adjacent ones of the plurality of gate electrodes, respectively, are arranged not so as to be adjacent to each other. Thus, increase in a circuit area can be suppressed.

In this case, if each of the plurality of gate electrodes is electrically connected, through a shared contact, to an associated one of the diodes located adjacent to the plurality of gate electrode, respectively, the width of a connection portion of the gate electrode connected with the shared contact can be preferably made to be the same as a gate length.

In one embodiment of the present invention, the gate electrode has branches arranged so as to be adjacent to each other and connected to diodes, respectively, and diodes connected to the branches, respectively, are arranged so as not to be adjacent to each other. Thus, increase in a circuit area can be suppressed.

A method for designing a semiconductor integrated circuit according to the present invention is a method for designing a semiconductor integrated circuit using a standard cell. The method includes the steps of: a) preparing a standard cell in which a MOS transistor including a gate electrode and a diode electrically connected to the gate electrode are provided; and b) disposing the standard cell by a design support apparatus.

According to the method, correction after a layout execution becomes no longer needed and a design period can be reduced.

### BRIEF DESCRIPTION OF THE DRAWINGS

FIG. 1A is a plan view illustrating a pattern of a semiconductor integrated circuit according to a first embodiment of the present invention when viewed from the top. FIG. 1B is an equivalent circuit diagram of the semiconductor integrated circuit of FIG. 1A.

FIG. 2A is a plan view illustrating a pattern of a semiconductor integrated circuit according to a second embodiment of the present invention when viewed from the top. FIG. 2B is a cross-sectional view of the semiconductor integrated circuit of FIG. 2A taken along the line IIB-IIB shown in FIG. 2A.

FIG. 3A is a plan view illustrating a pattern of a semiconductor integrated circuit according to a third embodiment of the present invention when viewed from the top. FIG. 3B is a cross-sectional view of the semiconductor integrated circuit of FIG. 3A taken along the line IIIb-IIIb shown in FIG. 3A.

FIG. 4A is a plan view illustrating a pattern of a semiconductor integrated circuit according to a fourth embodiment of the present invention when viewed from the top. FIG. 4B is a plan view illustrating a pattern of an input section of a buffer cell in the semiconductor integrated circuit of the fourth embodiment. FIG. 4C is a cross-sectional view of the semiconductor integrated circuit of FIG. 4B taken along the line IVC-IVC shown in FIG. 4A.

FIG. 5 is a flow chart illustrating a method for designing a semiconductor integrated circuit according to the present invention.

FIG. 6 is a flow chart illustrating a known measure against antenna damage.

### DESCRIPTION OF THE PREFERRED EMBODIMENTS

### First Embodiment

Hereinafter, a semiconductor integrated circuit according to a first embodiment of the present invention will be described with reference to the accompanying drawings.

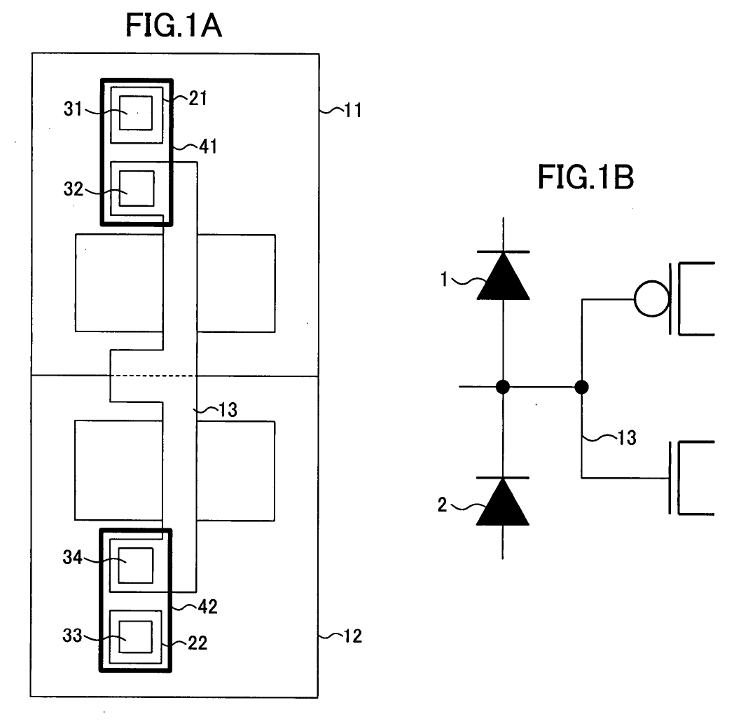

FIG. 1A is a plan view illustrating a pattern of a semiconductor integrated circuit according to the first embodiment of the present invention when viewed from the top. FIG. 1B is an equivalent circuit diagram of the semiconductor integrated circuit of FIG. 1A. In this case, as for a plurality of MOS transistors provided in the semiconductor integrated circuit, a first-conductive-type MOS transistor (for example, p-channel MOSFET) provided on a second-conductive-type well 11 and a second-conductive-type MOS transistor (for example, n-channel MOSFET) provided on a first-conductive-type well 12 are shown. In the semiconductor integrated circuit of this embodiment, at least one diode is connected to a gate electrode of the first and second-conductive-type MOS transistors.

As shown in FIG. 1A, when the semiconductor integrated circuit of the first embodiment is fabricated, a first-conductive-type doped layer 21 is provided on the second-conductive-type well 11 and the gate electrode 13 of the MOS transistors and the first-conductive-type doped layer 21 are connected to each other via a plug for filling contact holes 31 and 32 and a metal interconnect 41 of Cu or the like. Furthermore, a second-conductive-type doped layer 22 is provided on the first-conductive-type well 12 and the gate electrode 13 of the MOS transistors and the second-conductive-type doped layer 22 are connected to each other via a plug for filling contact holes 33 and 34 and a metal interconnect 42 of Cu or the like. Thus, a diode 1 and a diode 2 are provided between the gate electrode 13 of the MOS transistors and the second-conductive-type well 11 and between the gate electrode 13 of the MOS transistors and the first-conductive-type well 12, respectively. As described, in designing the semiconductor integrated circuit of this embodiment, automatic placement and routing using a standard cell is performed by a design support apparatus. In that case, a gate electrode provided in the standard cell is made to include at least one diode.

In the semiconductor integrated circuit of the first embodiment, as described above, the diode 1 is provided between the gate electrode 13 of the MOS transistors and the second-conductive-type well 11 and the diode 2 is provided between the gate electrode 13 of the MOS transistors and the first-conductive-type well 12. Thus, charges can be released to a substrate via the diode 1 or the diode 2 when the substrate is processed in plasma processing. For example, plasma charges generated when a metal interconnect is patterned can be released. Therefore, antenna damage imposed on the gate electrode 13 of the MOS transistors can be reduced.

Even when only one of the diode 1 and the diode 2 is connected to the gate electrode 13, plasma charges can be also absorbed. However, to discharge positive plasma charges and negative plasma charges in the forward direction before a large amount of charges are stored, it is particularly effective to provide both of the diode 1 and the diode 2.

As described above, the semiconductor integrated circuit of this embodiment is characterized in that for the gate electrode 13 to be connected by automatic placement and routing, at least one diode is provided beforehand in a standard cell in which the gate electrode 13 is provided. Thus, the number of designing steps of the semiconductor integrated circuit can be reduced in the manner as described below.

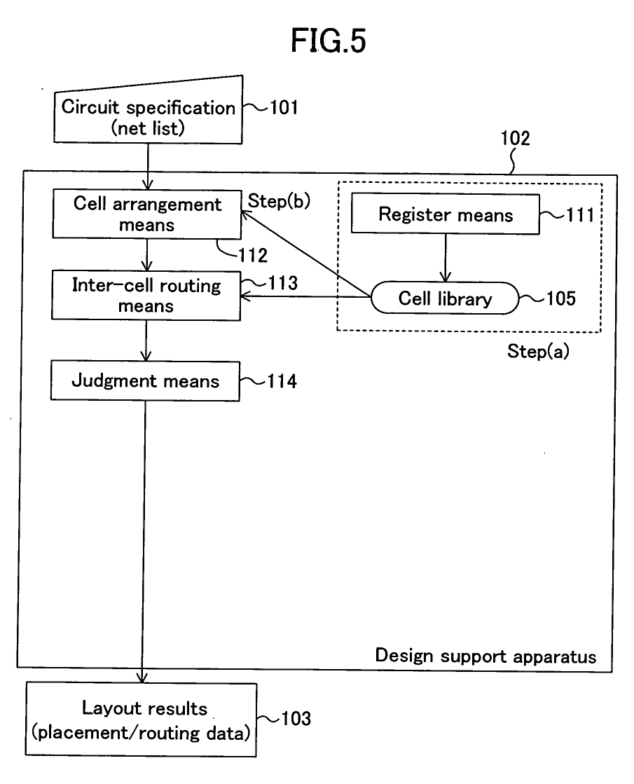

FIG. 5 is a flow chart illustrating a method for designing a semiconductor integrated circuit according to the present invention.

As shown in FIG. 5, in designing the semiconductor integrated circuit of this embodiment, a circuit specification 101 is determined.

Thereafter, a MOS transistor including a gate electrode and a standard cell including a diode connected to the gate electrode are prepared using a design support apparatus 102, and the standard cell is registered in a cell library 105 using register means 111 (Step (a)).

Subsequently, a cell arrangement means 112 places the standard cell prepared in Step (a) according to the circuit specification 101 (Step (b)).

Thereafter, an inter-cell routing means 113 generates an interconnect. Note that a judgment means 114 does not have to perform detection for part of a chip having a large antenna ratio. In the above-described manner, a layout result 103 for a semiconductor integrated circuit can be obtained.

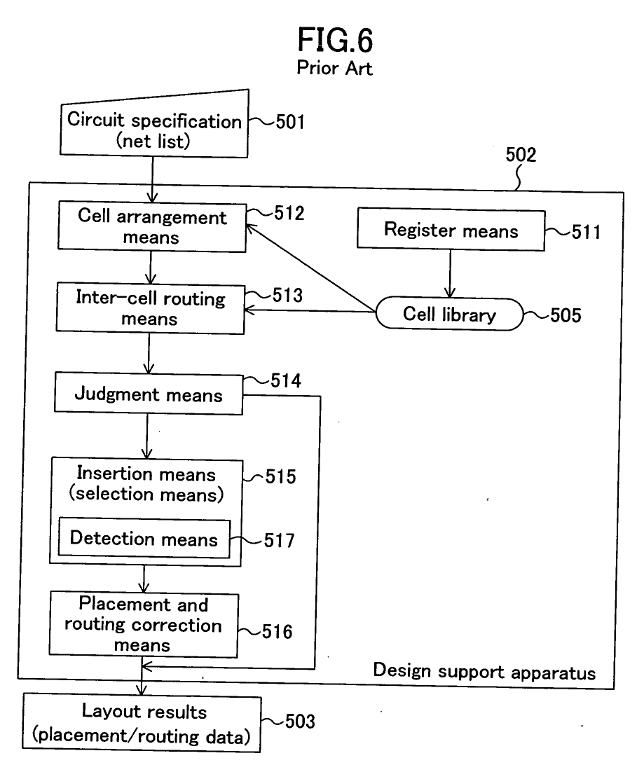

According to the designing method of this embodiment for designing a semiconductor integrated circuit, automatic placement and routing is performed using a standard cell in which a diode is provided beforehand to design a layout for a chip. Thus, unlike a known method, a situation where an antenna rule error is found after the layout of a chip is executed can be avoided and, therefore, correction of the antenna rule error after the execution of the layout, for example, by adding a diode to part of the chip in which the antenna error has occurred is not required. Moreover, manual design modification does not have to be performed. Therefore, design efficiency in designing a semiconductor device can be improved and thus a design turnaround time (design period) can be reduced. Specifically, compared to the known designing method of FIG. 6, the step of detecting part of a chip having a large antenna ratio using the judgment means 514, the step of inserting a diode, and the step of performing interconnection correction using the placement and routing correction means 516 can be omitted.

### Second Embodiment

Hereinafter, a semiconductor integrated circuit according to a second embodiment of the present invention will be described with reference to the accompanying drawings.

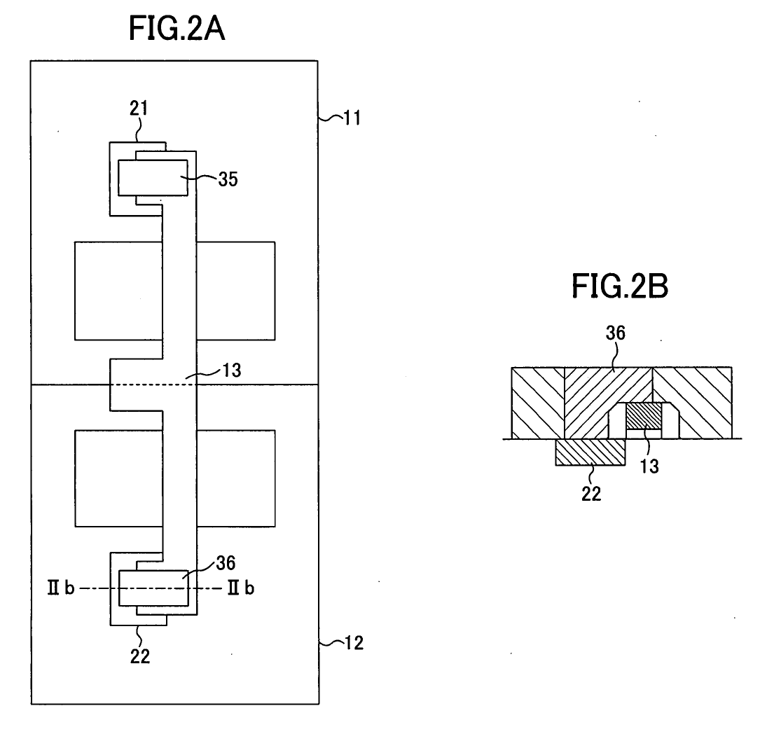

FIG. 2A is a plan view illustrating a pattern of a semiconductor integrated circuit according to the second embodiment of the present invention when viewed from the top. FIG. 2B is a cross-sectional view of the semiconductor integrated circuit of FIG. 2A taken along the line IIB-IIB shown in FIG. 2A.

As shown in FIG. 2A, in the semiconductor integrated circuit of the second embodiment, a first-conductive-type doped layer 21 is provided on a second-conductive-type well 11, and a gate electrode 13 of a MOS transistor and the first-conductive-type doped layer 21 are connected to each other via a plug for filling contact hole 35. Furthermore, a second-conductive-type doped layer 22 is provided on a first-conductive-type well 12, and the gate electrode 13 of the MOS transistors and the second-conductive-type doped layer 22 are connected to each other via a plug for filling a contact hole 36. Thus, a diode 1 and a diode 2 are provided between the gate electrode 13 of the MOS transistors and the second-conductive-type well 11 and between the gate electrode 13 of the MOS transistors and the first-conductive-type well 12, respectively.

In the second embodiment, the diode 1 is provided between the gate electrode 13 of the MOS transistors and the second-conductive-type well 11 and the second diode 2 is provided between the gate electrode 13 of the MOS transistors and the first-conductive-type well 12 in the above-described manner. Thus, plasma charges generated in patterning of a metal interconnect and the like can be absorbed and antenna damage imposed on the gate electrode 13 of the MOS transistors can be reduced.

In this case, even when only one of the diode 1 and the diode 2 is provided, plasma charges can be also absorbed. However, to discharge positive plasma charges and negative plasma charges in the forward direction before a large amount of charges are stored, it is particularly effective to provide both of the diode 1 and the diode 2.

Moreover, the semiconductor integrated circuit of this embodiment is characterized in that a shared contact structure of FIG. 2B in which a gate electrode and a doped layer are connected to each other via a single contact hole is adopted to the contact hole 35 (and the plug) connecting the gate electrode 13 and the second-conductive-type doped layer 22 and the contact hole 36 (and the plug) connecting the gate electrode 13 and the second-conductive-type doped layer 22.

Thus, increase in a chip area resulting from providing a diode in a semiconductor integrated circuit can be suppressed.

### Third Embodiment

Hereinafter, a semiconductor integrated circuit according to a third embodiment of the present invention will be described with reference to the accompanying drawings.

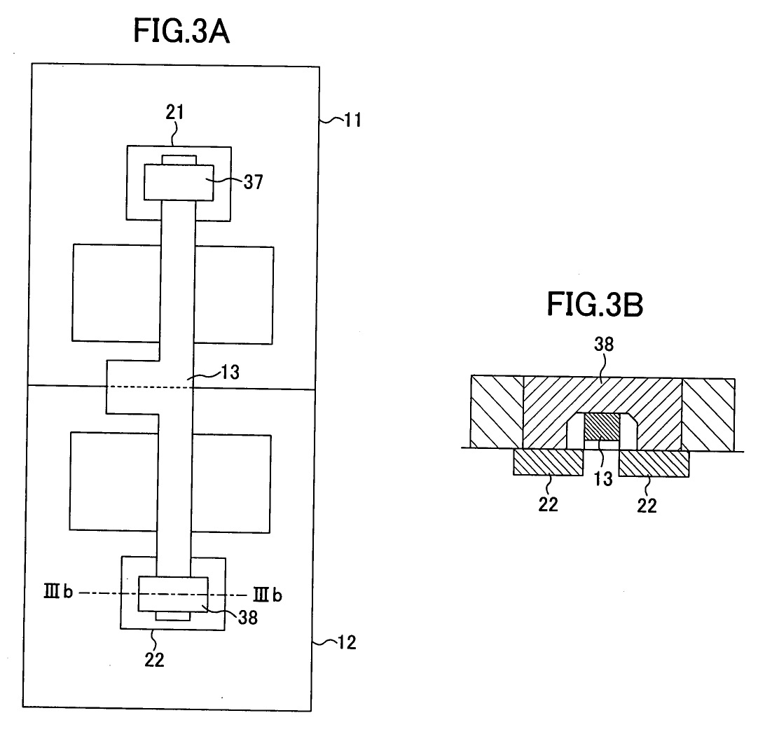

FIG. 3A is a plan view illustrating a pattern of a semiconductor integrated circuit according to the third embodiment of the present invention when viewed from the top. FIG. 3B is a cross-sectional view of the semiconductor integrated circuit of FIG. 3A taken along the line IIIb-IIIb shown in FIG. 3A.

As shown in FIG. 3A, in the semiconductor integrated circuit of the third embodiment, a first-conductive-type doped layer 21 is provided on a second-conductive-type well 11, and a gate electrode 13 of MOS transistors and the first-conductive-type doped layer 21 are connected to each other via a plug for filling contact hole 37. Furthermore, a second-conductive-type doped layer 22 is provided on a first-conductive-type well 12, and the gate electrode 13 of the MOS transistors and the second-conductive-type doped layer 22 are connected to each other via a plug for filling a contact hole 38. Thus, a diode 1 and a diode 2 are provided between the gate electrode 13 of the MOS transistors and the second-conductive-type well 11 and between the gate electrode 13 of the MOS transistors and the first-conductive-type well 12, respectively.

In the semiconductor integrated circuit of this embodiment, as in the semiconductor integrated circuits of the first and second embodiments, the first diode is provided between the gate electrode 13 of the MOS transistors and the second-conductive-type well 11 and the second diode 2 is provided between the gate electrode 13 of the MOS transistors and the first-conductive-type well 12 in the above-described manner. Thus, plasma charges generated in patterning a metal interconnect and the like can be absorbed and antenna damage imposed on the gate electrode 13 of the MOS transistors can be reduced.

In this case, even when only one of the diode 1 and the diode 2 is provided, plasma charges can be also absorbed. However, to discharge positive plasma charges and negative plasma charges in the forward direction before a large amount of charges are stored, it is particularly effective to provide both of the diode 1 and the diode 2.

This embodiment is characterized in that, as shown in FIG. 3B, to connect the gate electrode 13 of the MOS transistors and the second-conductive-type doped layer 22, a shared contact structure in which the gate electrode 13 and each of doped layers located on both sides of the gate electrode 13 are connected to each other via a single contact hole is adopted. In the same manner, to connect the gate electrode 13 and the first-conductive-type doped layer 21, a shared contact for connecting the gate electrode 13 and each of doped layers located on both sides of the gate electrode 13 via a single contact hole is adopted. In the semiconductor integrated circuit of the second embodiment, to reliably provide the contacts, widths of end portions of the gate electrode 13 have to be increased to provide margins. However, in the semiconductor integrated circuit of this embodiment, a shared contact is formed so as to extend astride the gate electrode 13. Thus, the width of the gate electrode 13 can be made constant from one end to the other end. It has been known that when an end portion of a gate electrode has a larger width than that of other part thereof, the shape of the end portion of the gate electrode becomes different from an expected value in diffusion processing and gate electrode formation. Therefore, forming a gate electrode so as to have expected dimensions has been one of challenges. In contrast, in the semiconductor integrated circuit of this embodiment, the width of the gate electrode 13 can be made constant from one end to the other end and, therefore, variation in gate shape after diffusion processing can be suppressed. Accordingly, in the semiconductor integrated circuit of this embodiment, the effect of suppressing variation in transistor characteristics due to the dependency on the shape of a gate electrode can be achieved. Moreover, as in the second embodiment, a shared contact structure is adopted. Therefore, increase in the area of a chip due to formation of a diode can be suppressed.

### Fourth Embodiment

Hereinafter, a semiconductor integrated circuit according to a fourth embodiment of the present invention will be described with the accompanying drawings.

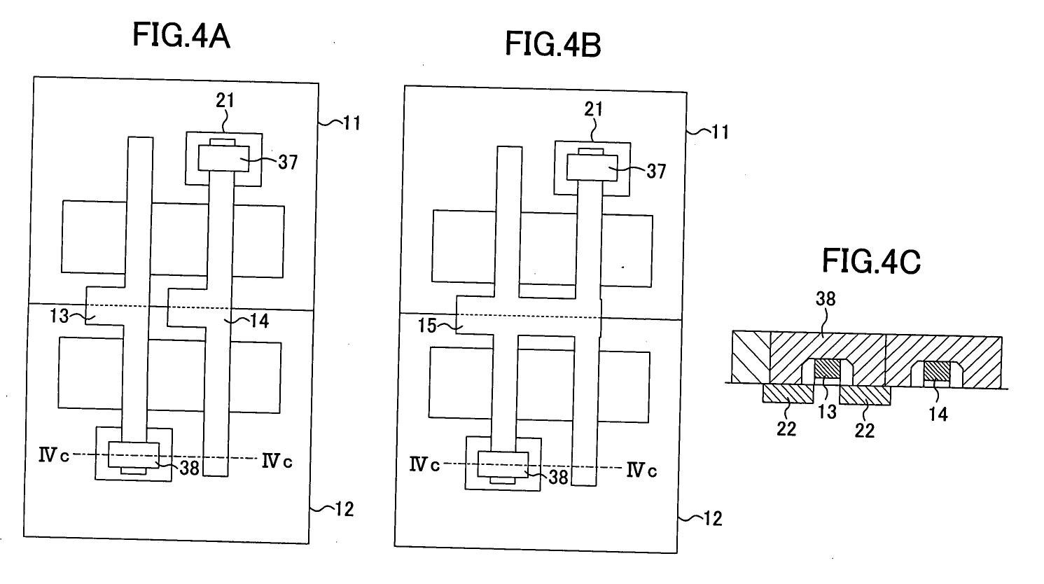

FIG. 4A is a plan view illustrating a pattern of a semiconductor integrated circuit according to the fourth embodiment of the present invention when viewed from the top. FIG. 4B is a plan view illustrating a pattern of an input section of a buffer cell in the semiconductor integrated circuit of the fourth embodiment. FIG. 4C is a cross-sectional view of the semiconductor integrated circuit of FIG. 4B taken along the line IVC-IVC shown in FIG. 4A.

As shown in FIG. 4A, in the semiconductor integrated circuit of the fourth embodiment, a first-conductive-type doped layer 21 is provided on a second-conductive-type well 11, and a gate electrode 14 of a MOS transistor and the first-conductive-type doped layer 21 are connected to each other via a plug for filling contact hole 37. Furthermore, a second-conductive-type doped layer 22 is provided on a first-conductive-type well 12, and the gate electrode 13 of a MOS transistor and the second-conductive-type doped layer 22 are connected to each other via a plug for filling a contact hole 38. Thus, a diode 1 and a diode 2 are provided between the gate electrode 14 of the MOS transistor and the second-conductive-type well 11 and between the gate electrode 13 of the MOS transistor and the first-conductive-type well 12, respectively.

In the semiconductor integrated circuit of FIG. 4B, the gate electrode 13 and the gate electrode 14 are provided so as to be arranged substantially in parallel and not to be connected to each other. The diode 1 including the first-conductive-type doped layer 21 and the second-conductive-type well 11 is provided between the gate electrode 14 and the second-conductive-type well 11 and the diode 2 including the second-conductive-type doped layer 22 and the first-conductive-type well 12 is provided between the gate electrode 13 and the first-conductive-type well 12. Thus, plasma charges generated in patterning a metal interconnect and the like can be absorbed and antenna damage imposed on the gate electrodes 13 and 14 of the MOS transistors can be reduced.

Moreover, as shown in FIG. 4B, in an example where the semiconductor integrated circuit of the fourth embodiment is used as an input section of a buffer cell, a first-conductive-type doped layer 21 is provided on a second-conductive-type well 11, and a gate electrode 15 of a MOS transistor and the first-conductive-type doped layer 21 are connected to each other via a plug for filling a contact hole 37. Furthermore, the second-conductive-type doped layer 22 is provided on the first-conductive-type well 12, and the gate electrode 15 of a MOS transistor and the second-conductive-type doped layer 22 are connected to each other via a plug for filling a contact hole 38. Then, a diode 1 and a diode 2 are provided between the gate electrode 15 and the second-conductive-type well 11 and between the gate electrode 15 of the MOS transistor and the first-conductive-type well 12, respectively.

In the example of FIG. 4B where the semiconductor integrated circuit of this embodiment is adopted to an input section of a buffer cell, the diode 1 is provided between the gate electrode 15 and the second-conductive-type well 11 and the diode 2 is provided between the gate electrode 15 and the first-conductive-type well 12 in the above-described manner. Thus, positive plasma charges and negative plasma charges generated in patterning a metal interconnect can be discharged in the forward direction before a large amount of charges are stored and thus antenna damage imposed on the gate electrode 15 of the MOS transistor can be reduced.

The semiconductor device of this embodiment is characterized in that when a plurality of gate electrodes are arranged in parallel to one another, diodes connected to adjacent ones of the plurality of gate electrodes are arranged so as not to be adjacent to each other. In other words, diodes connected to adjacent ones of the plurality of gate electrodes are arranged on a diagonal line (in a staggered configuration). Moreover, when a single gate electrode has parts extending in parallel to each other, diodes provided in end portions are arranged in a staggered configuration so as not to be adjacent to each other.

Thus, increase in the area of a chip in the lateral direction (in the direction of extension of the cross-section of FIG. 4C) due to providing a diode in a semiconductor integrated circuit can be suppressed.

Note that in the example of FIGS. 4A through 4C, a shared contact provided in each of the both sides of a gate electrode is used as a connection between a diode and a gate electrode. However, the contact of each of the first, second and third embodiments may be used. Note that when a shared contact is used, the width of a connection portion of a gate electrode connected with the contact can be preferably made the same as a gate length.

As has been described, a method for designing a semiconductor device according to the present invention is useful for a method for preventing antenna damage due to the antenna effect generated in plasma processing when forming a metal film interconnect in a semiconductor process.

What is claimed is:

1. A semiconductor integrated circuit designed using a standard cell, wherein in the standard cell, at least one diode and one or more MOS transistors each comprising a gate electrode are provided, said at least one diode being electrically connected to the gate electrode.

2. The semiconductor integrated circuit of clam 1, wherein said at least one diode includes a first-conductive-type doped layer electrically connected to the gate electrode and a second-conductive-type well.

3. The semiconductor integrated circuit of claim 1, wherein as the one or more MOS transistors, a plurality of MOS transistors are provided in the standard cell so as to share the gate electrode, and
wherein the plurality of MOS transistors includes a p-type MOS transistor and an n-type MOS transistor.

4. The semiconductor integrated circuit of claim 1, wherein said at least one diode is provided plural in number in the standard cell,
wherein the plurality of diodes include
a first diode including a first-conductive-type doped layer electrically connected to the gate electrode, and a second-conductive-type well, and
a second diode including a second-conductive-type doped layer electrically connected to the gate electrode, and a first-conductive-type well.

5. The semiconductor integrated circuit of claim 1, wherein the gate electrode and said at least one diode are electrically connected to each other via a shared contact.

6. The semiconductor integrated circuit of claim 5, wherein the shared contact connects the gate electrode and said at least one diode at each side of the gate electrode.

7. The semiconductor integrated circuit of claim 6, wherein a width of a connection portion of the gate electrode connected with the shared contact is the same as a gate length of the MOS transistor.

8. The semiconductor integrated circuit of claim 1, wherein the gate electrode is provided plural in number in the standard cell, and
wherein diodes connected to adjacent ones of the plurality of gate electrodes, respectively, are arranged not so as to be adjacent to each other.

9. The semiconductor integrated circuit of claim 8, wherein each of the plurality of gate electrodes is electrically connected, through a shared contact, to an associated one of the diodes located adjacent to the plurality of gate electrode, respectively.

10. The semiconductor integrated circuit of claim 1, wherein the gate electrode has branches arranged so as to be adjacent to each other and connected to diodes, respectively, and
wherein diodes connected to the branches, respectively, are arranged so as not to be adjacent to each other.

11. A method for designing a semiconductor integrated circuit using a standard cell, the method comprising the steps of:
a) preparing a standard cell in which a MOS transistor including a gate electrode and a diode electrically connected to the gate electrode are provided; and
b) disposing the standard cell by a design support apparatus.
